(19) United States
(12) Patent Application Publication
(10) Pub. No.: US 2023/0411071 A1
(43) Pub. Date: Dec. 21, 2023

(54) POWER CONVERSION DEVICE

(71) Applicant: FUJI ELECTRIC CO., LTD., Kawasaki-shi (JP)

(72) Inventor: Masaki SAKUMA, Amagasaki-shi (JP)

(21) Appl. No.: 18/302,946

(22) Filed: Apr. 19, 2023

(30) Foreign Application Priority Data
Jun. 17, 2022 (JP) 2022-098040

(51) Int. Cl. H01F 27/32; H01F 27/36; H05K 7/14; H05K 7/20

(52) U.S. Cl. CPC H01F 27/32; H01F 27/36; H05K 7/1432; H05K 7/20918

(57) ABSTRACT

A power conversion device includes a transformer including a core and a coil wound around the core, a substrate made of resin, on which the transformer is mounted, and a housing made of metal, arranged on a side of the transformer opposite to the substrate, and including a recessed transformer accommodating portion to accommodate the transformer. An insulating layer is provided in a portion of the transformer accommodating portion that faces the coil in a direction in which the substrate and the housing face each other.

### CROSS-REFERENCE TO RELATED APPLICATION

The present application claims priority of Japanese Patent Application No. 2022-098040 filed Jun. 17, 2022, the disclosure of which is hereby incorporated by reference.

### BACKGROUND OF THE INVENTION

### Field of the Invention

The present invention relates to a power conversion device.

### Description of the Background Art

A power conversion device including a transformer is known in general, as disclosed in Japanese Patent Laid-Open No. 2013-090533, for example.

Japanese Patent Laid-Open No. 2013-090533 discloses an electric power supply (power conversion device) including a transformer and a metal housing that houses the transformer.

In an electric power supply (power conversion device) as described in Japanese Patent Laid-Open No. 2013-090533, a transformer is housed in a metal housing, and thus the leakage magnetic flux of the transformer is likely to be interlinked with a portion of the metal housing in which the transformer is housed. In other words, eddy currents are likely to occur in the portion of the metal housing in which the transformer is housed due to the leakage magnetic flux of the transformer. Eddy current losses (power losses) occur when eddy currents occur in the portion of the metal housing in which the transformer is housed. Therefore, a configuration capable of reducing or preventing eddy current losses due to the leakage magnetic flux of the transformer is desired.

### SUMMARY OF THE INVENTION

The present invention has been proposed in order to solve the aforementioned problems, and an object of the present invention is to provide a power conversion device capable of reducing or preventing eddy current losses due to the leakage magnetic flux of a transformer.

In order to attain the aforementioned object, a power conversion device according to an aspect of the present invention includes a transformer including a core and a coil wound around the core; a substrate made of resin, on which the transformer is mounted; a housing made of metal, arranged on a side of the transformer opposite to the substrate, and including a recessed transformer accommodating portion to accommodate the transformer; and an insulating layer provided in a portion of the transformer accommodating portion that faces the coil in a direction in which the substrate and the housing face each other.

In the power conversion device according to this aspect of the present invention, as described above, the insulating layer is provided in the portion of the transformer accommodating portion that faces the coil in the direction in which the substrate and the housing face each other. Accordingly, even when the leakage magnetic flux of the transformer passes through the insulating layer, eddy currents do not occur in the insulating layer, and thus as compared with a case in which the portion of the transformer accommodating portion that faces the coil in the direction in which the substrate and the housing face each other is not the insulating layer but metal of which the housing is made, the occurrence of eddy currents in the portion of the transformer accommodating portion that faces the coil in the direction in which the substrate and the housing face each other can be reduced or prevented. Consequently, eddy current losses due to the leakage magnetic flux of the transformer can be reduced or prevented.

In the power conversion device according to this aspect, the transformer accommodating portion of the housing preferably includes a frame-shaped first portion made of metal, in which the core is arranged, and a second portion provided inside the first portion and formed as the insulating layer, in which the coil is arranged. Accordingly, the second portion formed as the insulating layer of the transformer accommodating portion faces the coil in the direction in which the substrate and the housing face each other, and thus the insulating layer can be easily provided in the portion of the transformer accommodating portion that faces the coil in the direction in which the substrate and the housing face each other.

In this case, the second portion formed as the insulating layer preferably includes a bottom facing the coil as viewed in the direction in which the substrate and the housing face each other, and side portions continuous with the bottom, extending along the direction in which the substrate and the housing face each other, and surrounding the coil. Accordingly, as compared with a case in which the side portions are not formed as the insulating layer and are made of metal of which the housing is made, the occurrence of eddy currents in the transformer accommodating portion can be further reduced or prevented.

In the power conversion device according to this aspect, the insulating layer preferably includes an insulating member fitted into a hole provided in the portion of the transformer accommodating portion that faces the coil in the direction in which the substrate and the housing face each other.

Accordingly, the insulating layer including the insulating member can be easily provided in the portion of the transformer accommodating portion that faces the coil in the direction in which the substrate and the housing face each other simply by fitting the insulating member into the hole.

In this case, the power conversion device preferably further includes a cooling fin provided on a surface of the insulating layer including the insulating member on a side opposite to the transformer. Accordingly, the insulating member can be efficiently cooled as compared with a case in which the cooling fin is not provided on the surface of the insulating member on the side opposite to the transformer. Consequently, as compared with a case in which the cooling fin is not provided on the surface of the insulating layer including the insulating member on the side opposite to the transformer, the transformer can be efficiently cooled via the insulating member.

In the power conversion device according to this aspect, the insulating layer preferably is a space as a hole provided in the portion of the transformer accommodating portion that faces the coil in the direction in which the substrate and the housing face each other. Accordingly, the insulating layer formed of air can be easily provided in the portion of the transformer accommodating portion that faces the coil in the direction in which the substrate and the housing face each other simply by providing a space in the portion of the transformer accommodating portion that faces the coil. Moreover, unlike a case in which the insulating layer includes the insulating member, the insulating member is not required, and thus the number of components can be reduced.

The power conversion device according to this aspect preferably further includes a cover member made of metal to cover the housing on a side of the transformer accommodating portion opposite to the transformer, and a plate-shaped shielding member provided between the transformer accommodating portion and the cover member to shield a leakage magnetic flux of the transformer. Although eddy currents do not occur in the insulating layer, the insulating layer allows the leakage magnetic flux of the transformer to pass therethrough. Therefore, eddy currents may occur in the metal cover member arranged on the side of the transformer accommodating portion opposite to the transformer. Therefore, the shielding member is provided between the transformer accommodating portion and the cover member as described above such that interlinkage of the leakage magnetic flux of the transformer with the metal cover member that covers the housing on the side of the transformer accommodating portion opposite to the transformer can be reduced or prevented by the shielding member. Consequently, as compared with a case in which the shielding member is not provided between the transformer accommodating portion and the cover member, the occurrence of eddy currents in the metal cover member can be reduced or prevented, and thus eddy current losses can be reduced or prevented.

In this case, the shielding member is preferably made of at least one of non-magnetic metal having an electrical resistance lower than an electrical resistance of the cover member or ferrite. Eddy current losses are proportional to the electrical resistance of a member in which eddy currents occur, and thus eddy current losses due to eddy currents occurring in the shielding member when the leakage magnetic flux of the transformer is interlinked with the shielding member made of non-magnetic metal having an electrical resistance lower than the electrical resistance of the cover member are likely to be smaller than eddy current losses due to eddy currents occurring in the cover member when the leakage magnetic flux of the transformer is interlinked with the cover member. Furthermore, the amount of leakage magnetic flux of the transformer interlinked with the cover member is reduced by the amount of leakage magnetic flux of the transformer interlinked with the shielding member provided between the transformer accommodating portion and the cover member. Therefore, the shielding member is made of non-magnetic metal having an electrical resistance lower than the electrical resistance of the housing as described above such that eddy current losses due to eddy currents occurring in the metal cover member can be easily reduced or prevented. Moreover, ferrite has the effect of attracting a magnetic flux, and thus when the shielding member made of ferrite is provided between the transformer accommodating portion and the cover member, the leakage magnetic flux of the transformer is less likely to be interlinked with the cover member as compared with a case in which the shielding member made of ferrite is not provided between the transformer accommodating portion and the cover member. Therefore, as described above, the shielding member is made of ferrite such that the leakage magnetic flux of the transformer is less likely to be interlinked with the cover member, and thus the occurrence of eddy currents in the cover member can be easily reduced or prevented. Thus, eddy current losses due to eddy currents occurring in the cover member can be easily reduced or prevented.

In the configuration including the shielding member, the shielding member preferably has a size substantially equal to or larger than a size of the insulating layer, as viewed in the direction in which the substrate and the housing face each other. Accordingly, the shielding member is relatively large as viewed in the direction in which the substrate and the housing face each other, and thus the leakage magnetic flux of the transformer toward the metal cover member can be effectively shielded.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram of a power conversion device according to an embodiment of the present invention;

FIG. 2 is a perspective view of the power conversion device according to the embodiment of the present invention;

FIG. 3 is an exploded perspective view of the power conversion device according to the embodiment of the present invention;

FIG. 4 is a perspective view showing a housing of the power conversion device according to the embodiment of the present invention, as viewed from the side opposite to the side on which a transformer is housed;

FIG. 5 is a perspective view showing the transformer and the housing of the power conversion device according to the embodiment of the present invention;

FIG. 6 is a sectional view showing the vicinity of a transformer accommodating portion of the power conversion device according to the embodiment of the present invention;

FIG. 7 is a perspective view showing the transformer accommodating portion of the power conversion device according to the embodiment of the present invention;

FIG. 8 is a sectional view showing the vicinity of a transformer accommodating portion of a power converter device according to a first modified example of the present invention;

FIG. 9 is a sectional view showing the vicinity of a transformer accommodating portion of a power converter device according to a second modified example of the present invention;

FIG. 10 is a sectional view showing the vicinity of a transformer accommodating portion of a power converter device according to a third modified example of the present invention;

FIG. 11 is a sectional view showing the vicinity of a transformer accommodating portion of a power converter device according to a fourth modified example of the present invention;

FIG. 12 is a sectional view showing the vicinity of a transformer accommodating portion of a power converter device according to a fifth modified example of the present invention;

FIG. 13 is a sectional view showing the vicinity of a transformer accommodating portion of a power converter device according to a sixth modified example of the present invention;

FIG. 14 is a sectional view showing the vicinity of a transformer accommodating portion of a power converter device according to a seventh modified example of the present invention; and

FIG. 15 is a sectional view showing the vicinity of a transformer accommodating portion of a power converter device according to an eighth modified example of the present invention.

### DESCRIPTION OF THE PREFERRED EMBODIMENTS

An embodiment of the present invention is hereinafter described with reference to the drawings.

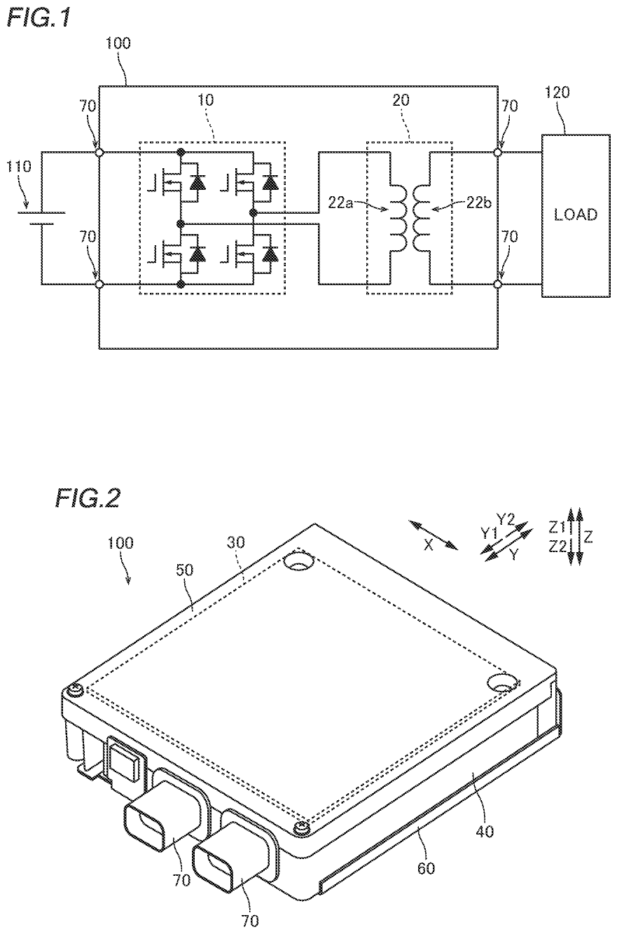

The configuration of a power conversion device 100 according to the embodiment of the present invention is now described with reference to FIGS. 1 to 7.

### Overall Configuration of Power Conversion Device

As shown in FIG. 1, the power conversion device 100 converts DC power supplied from a power source (battery, for example) 110 into AC power, converts the voltage of the AC power into a predetermined voltage, and outputs the predetermined voltage to a load 120. Specifically, the power conversion device 100 includes a power converter 10 and a transformer 20. The power converter 10 converts the DC power supplied from the power source 110 into AC power. The transformer 20 converts the voltage of the AC power output from the power converter 10 and outputs the converted voltage to the load 120. The power conversion device 100 is an in-vehicle power supply mounted on a vehicle, for example.

In the following description, the right-left direction, the forward-rearward direction, and the upward-downward direction of the power conversion device 100 are defined as an X direction, a Y direction, and a Z direction, respectively. Furthermore, the front side and the rear side of the power conversion device 100 are defined as a Y1 side and a Y2 side, respectively. The upper side and the lower side of the power conversion device 100 are defined as a Z1 side and a Z2 side, respectively.

As shown in FIG. 2, the power conversion device 100 includes a substrate 30, a housing 40, an upper cover member 50, a lower cover member 60, and connectors 70. The lower cover member 60 is an example of a “cover member” in the claims.

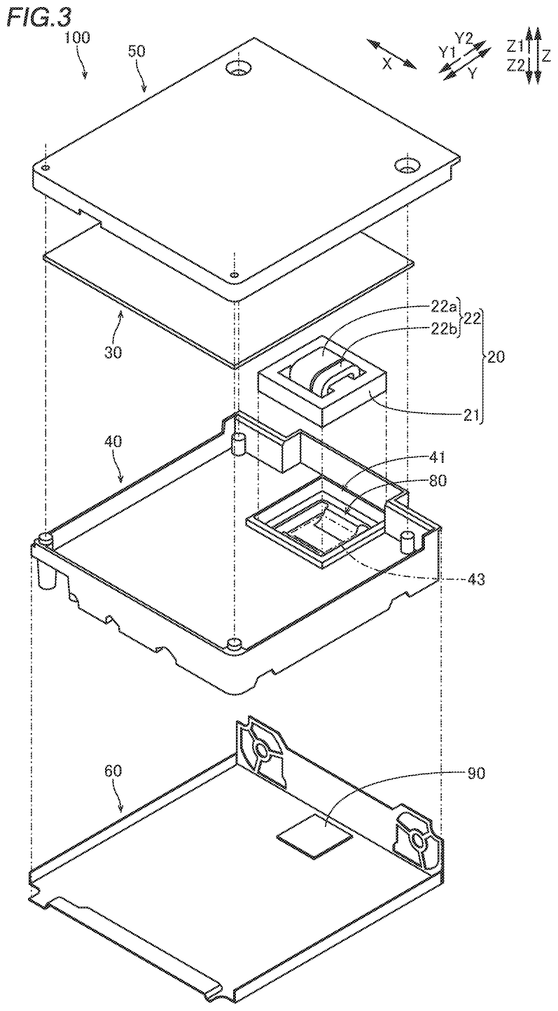

As shown in FIG. 3, the substrate 30 has a plate shape. On the Z2 side of the substrate 30, electronic components such as components of the power converter 10 and the transformer 20 are mounted. The substrate 30 is made of resin. In FIGS. 3, 5, and 7, illustration of electronic components other than the transformer 20 among the electronic components mounted on the substrate 30 is omitted.

The housing 40 is arranged on the side (Z2 side) opposite to the substrate 30 with respect to the electronic components (such as the transformer 20) mounted on the Z2 side of the substrate 30. The housing 40 houses the electronic components mounted on the substrate 30. Specifically, the housing 40 includes a recessed transformer accommodating portion 41 in which the transformer 20 is accommodated. The transformer accommodating portion 41 is provided on the Y2 side in the housing 40. The housing 40 is made of metal (aluminum, for example).

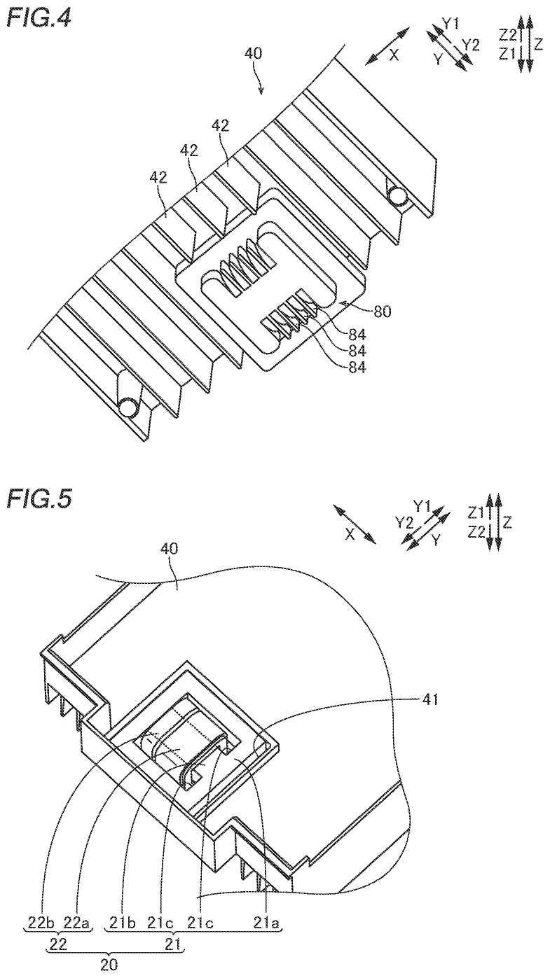

As shown in FIG. 4, a plurality of cooling fins 42 is provided on a surface of the housing 40 opposite (Z2 side) to the transformer 20 (see FIG. 3). On the Z2 side of the housing 40, air (cooling air) taken from the outside of the power conversion device 100 by a fan (not shown) passes. The fins 42 are cooled with the cooling air such that the housing 40 is cooled. The housing 40 is cooled such that the electronic components (such as the transformer 20) housed in the housing 40 are indirectly cooled. In the power conversion device 100, the electronic components housed in the housing 40 are efficiently cooled, and thus a clearance between the transformer 20 and the transformer accommodating portion 41 in the Z direction is relatively small. The clearance between the transformer 20 and the transformer accommodating portion 41 in the Z direction is described below.

As shown in FIG. 2, the upper cover member 50 covers the substrate 30 on the side (Z1 side) of the substrate 30 opposite to the transformer 20. Furthermore, the lower cover member 60 covers the housing 40 on the side (Z2 side) of the transformer accommodating portion 41 (i.e., the housing 40) opposite to the transformer 20. That is, as shown in FIG. 3, the upper cover member 50, the substrate 30, the housing 40, and the lower cover member 60 are aligned in this order from the Z1 side to the Z2 side. The upper cover member 50 and the lower cover member 60 are made of metal (iron, for example).

As shown in FIG. 2, the connectors 70 are terminals for connecting the power conversion device 100 to devices (such as the power source 110 and the load 120) outside the power conversion device 100. The connectors 70 are provided on the Y1 side of the housing 40. In FIG. 3, illustration of the connectors 70 is omitted.

### Configuration of Transformer

As shown in FIG. 5, the transformer 20 includes a core 21 and a coil 22 wound around the core 21.

The core 21 includes a rectangular and annular portion 21a as viewed in the Z direction, and a connection portion 21b extending in the X direction so as to connect a portion of the annular portion 21a on one side in the X direction to a portion of the annular portion 21a on the other side in the X direction in a hole inside the annular portion 21a. Thus, in the core 21, a through-hole 21c penetrating through the core 21 in the Z direction is formed on each of the Y1 side and the Y2 side of the connection portion 21b. The core 21 is made of a magnetic material such as ferrite.

The coil 22 is wound along a Y-Z plane around the connection portion 21b extending in the X direction. The coil 22 passes along the Z direction through the through-hole 21c formed on the Y1 side of the connection portion 21b and the through-hole 21c formed on the Y2 side of the connection portion 21b. The coil 22 includes a primary coil 22a and a secondary coil 22b. The primary coil 22a and the secondary coil 22b are aligned in the X direction.

### Structure for Reducing or Preventing Eddy Current Losses Due to Leakage Magnetic Flux of Transformer

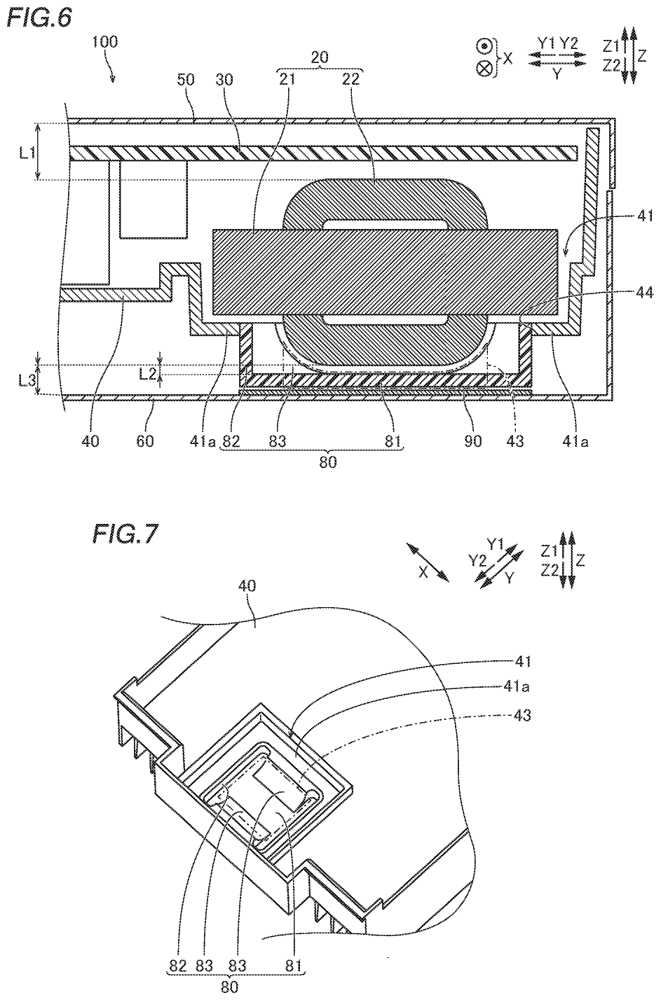

As shown in FIG. 6, the coil 22 of the transformer 20 is spaced apart from the metal upper cover member 50 by a distance L1 in the Z direction. The coil 22 of the transformer 20 is spaced apart from the transformer accommodating portion 41 of the housing 40 by a distance L2 in the Z direction. The distance L2 is smaller than the distance L1. The density (magnetic flux density) of the leakage magnetic flux of the transformer 20 attenuates as a distance from the transformer 20 increases. Therefore, in a direction (Z direction) in which the substrate 30 and the housing 40 face each other, the leakage magnetic flux of the transformer 20 is likely to be interlinked with the transformer accommodating portion 41 when a portion 43 of the transformer accommodating portion 41 that faces the coil 22 is made of metal. That is, eddy currents are likely to occur in the transformer accommodating portion 41 due to the leakage magnetic flux of the transformer 20. When eddy currents occur in the transformer accommodating portion 41, eddy current losses (power losses) occur.

Therefore, in the power conversion device 100, an insulating layer is provided in the entire portion 43 of the transformer accommodating portion 41 that faces the coil 22 in the direction (Z direction) in which the substrate 30 and the housing 40 face each other. Specifically, as shown in FIG. 7, the transformer accommodating portion 41 of the housing 40 includes a frame-shaped first portion 41a made of metal, in which the core 21 is arranged, as viewed in the Z direction, and a second portion 80 provided inside the first portion 41a and formed as the insulating layer, in which the coil 22 is arranged. A range in which the second portion 80 is provided includes all of the portion 43 and is wider than the portion 43, as viewed in the Z direction. Thus, eddy currents are less likely to occur in the portion 43 of the transformer accommodating portion 41 that faces the coil 22, unlike a case in which the insulating layer is provided in a relatively narrow range (in a slit shape, for example). As described below, the insulating layer includes an insulating member. The first portion 41a is made of metal (aluminum, for example) of which the housing 40 is made.

The second portion 80 formed as the insulating layer includes a bottom 81 facing the coil 22 (see FIG. 6) as viewed in the direction (Z direction) in which the substrate 30 (see FIG. 6) and the housing 40 face each other, side portions 82 continuous with the bottom 81, extending along the direction in which the substrate 30 and the housing 40 face each other, and surrounding the coil 22, and inclined portions 83 continuous with the bottom 81 and inclined with respect to the direction in which the substrate 30 and the housing 40 face each other. The second portion 80 is defined by the bottom 81, the side portions 82, and the inclined portions 83, and is recessed.

The bottom 81 includes a pair of Y-direction extension portions extending in the Y direction, and an X-direction extension portion extending in the X direction so as to connect central portions of the pair of Y-direction extension portions in the Y direction to each other. That is, the bottom 81 has an H-shape as viewed in the Z direction. The side portion 82 is arranged on the Y1 side, the Y2 side, and the outside in the X direction of each of the pair of Y-direction extension portions. The inclined portions 83 are arranged on each of the Y1 side and the Y2 side of the X-direction extension portion of the bottom 81. As shown in FIG. 6, each of the inclined portions 83 has a curved shape along the shape of the coil 22.

The second portion 80 (insulating layer) includes the insulating member fitted into a hole 44 provided in the portion 43 of the transformer accommodating portion 41 that faces the coil 22 in the direction (Z direction) in which the substrate 30 and the housing 40 face each other. Specifically, the hole 44 into which the insulating member of the second portion 80 is fitted is provided in the portion 43 of the transformer accommodating portion 41 that faces the coil 22. The insulating member is fitted into the hole 44. That is, the second portion 80 is formed by replacing a portion of the metal housing 40 with the insulating member. The insulating member of the second portion 80 is made of resin (PPS (polyphenylene sulfide), for example).

As shown in FIG. 4, cooling fins 84 are provided on a surface of the second portion 80 (insulating layer) including the insulating member on the side (Z2 side) opposite to the transformer 20. The fins 84 are provided on the Z2-side surfaces of the inclined portions 83 (see FIG. 7) of the second portion 80. The fins 42 have the same function as the fins 42 provided on the Z2-side surface of the housing 40.

As shown in FIG. 6, the coil 22 of the transformer 20 is spaced apart from the metal lower cover member 60 by a distance L3 in the Z direction. The distance L3 is larger than the distance L2 but smaller than the distance L1. Although eddy currents do not occur in the second portion 80 (insulating layer), the second portion 80 allows the leakage magnetic flux of the transformer 20 to pass therethrough. Therefore, the leakage magnetic flux of the transformer 20 may be interlinked with the metal lower cover member 60 provided on the side (Z2 side) of the transformer accommodating portion 41 opposite to the transformer 20. In other words, eddy currents may occur in the lower cover member 60. When eddy currents occur in the metal lower cover member 60, eddy current losses (power losses) occur.

Therefore, the power conversion device 100 includes a plate-shaped shielding member 90 to shield the leakage magnetic flux of the transformer 20 on the Z2 side. The shielding member 90 is provided between the transformer accommodating portion 41 and the lower cover member 60. The shielding member 90 is attached to the lower cover member 60. That is, the shielding member 90 is provided on the lower cover member 60 side between the transformer accommodating portion 41 and the lower cover member 60. The shielding member 90 is made of non-magnetic metal (copper, for example) having an electrical resistance lower than the electrical resistance of the lower cover member 60. As shown in FIG. 3, the shielding member 90 has a size substantially equal to or larger than the size of the second portion 80 (insulating layer), as viewed in the direction (Z direction) in which the substrate 30 and the housing 40 face each other. FIGS. 3 and 6 show an example in which the shielding member 90 has a size substantially equal to the size of the second portion 80, as viewed in the direction (Z direction) in which the substrate 30 and the housing 40 face each other.

Advantageous Effects of the Embodiment

According to this embodiment, the following advantageous effects are achieved.

According to this embodiment, as described above, the insulating layer (second portion 80) is provided in the portion 43 of the transformer accommodating portion 41 that faces the coil 22 in the direction (Z direction) in which the substrate 30 and the housing 40 face each other. Accordingly, even when the leakage magnetic flux of the transformer 20 passes through the insulating layer, eddy currents do not occur in the insulating layer, and thus as compared with a case in which the portion 43 of the transformer accommodating portion 41 that faces the coil 22 in the direction in which the substrate 30 and the housing 40 face each other is not the insulating layer but metal of which the housing 40 is made, the occurrence of eddy currents in the portion 43 of the transformer accommodating portion 41 that faces the coil 22 in the direction in which the substrate 30 and the housing 40 face each other can be reduced or prevented. Consequently, eddy current losses due to the leakage magnetic flux of the transformer 20 can be reduced or prevented.

According to this embodiment, as described above, the transformer accommodating portion 41 of the housing 40 includes the frame-shaped first portion 41a made of metal, in which the core 21 is arranged, and the second portion 41a provided inside the first portion 41a and formed as the insulating layer, in which the coil 22 is arranged. Accordingly, the second portion formed as the insulating layer of the transformer accommodating portion 41 faces the coil 22 in the direction (Z direction) in which the substrate 30 and the housing 40 face each other, and thus the insulating layer can be easily provided in the portion 43 of the transformer accommodating portion 41 that faces the coil 22 in the direction in which the substrate 30 and the housing 40 face each other.

According to this embodiment, as described above, the second portion 80 formed as the insulating layer includes the bottom 81 facing the coil 22 as viewed in the direction (Z direction) in which the substrate 30 and the housing 40 face each other, and the side portions 82 continuous with the bottom 81, extending along the direction in which the substrate 30 and the housing 40 face each other, and surrounding the coil 22. Accordingly, as compared with a case in which the side portions 82 are not formed as the insulating layer and are made of metal of which the housing 40 is made, the occurrence of eddy currents in the transformer accommodating portion 41 can be further reduced or prevented.

According to this embodiment, as described above, the second portion 80 (insulating layer) includes the insulating member fitted into the hole 44 provided in the portion 43 of the transformer accommodating portion 41 that faces the coil 22 in the direction (Z direction) in which the substrate 30 and the housing 40 face each other. Accordingly, the insulating layer including the insulating member can be easily provided in the portion 43 of the transformer accommodating portion 41 that faces the coil 22 in the direction in which the substrate 30 and the housing 40 face each other simply by fitting the insulating member into the hole 44.

According to this embodiment, as described above, the cooling fins 84 are provided on the surface of the second portion 80 (insulating layer) including the insulating member on the side (Z2 side) opposite to the transformer 20. Accordingly, the insulating member can be efficiently cooled as compared with a case in which the cooling fins 84 are not provided on the surface of the insulating member on the side opposite to the transformer 20. Consequently, as compared with a case in which the cooling fins 84 are not provided on the surface of the second portion 80 (insulating layer) including the insulating member on the side opposite to the transformer the transformer 20 can be efficiently cooled via the insulating member.

According to this embodiment, as described above, the power conversion device 100 includes the metal lower cover member 60 to cover the housing 40 on the side of the transformer accommodating portion 41 opposite to the transformer 20, and the plate-shaped shielding member 90 provided between the transformer accommodating portion 41 and the lower cover member 60 to shield the leakage magnetic flux of the transformer 20. Although eddy currents do not occur in the second portion 80 (insulating layer), the second portion 80 allows the leakage magnetic flux of the transformer 20 to pass therethrough. Therefore, eddy currents may occur in the metal lower cover member 60 arranged on the side (Z2 side) of the transformer accommodating portion 41 opposite to the transformer 20. Therefore, the shielding member 90 is provided between the transformer accommodating portion 41 and the lower cover member 60 as described above such that interlinkage of the leakage magnetic flux of the transformer 20 with the metal lower cover member 60 that covers the housing 40 on the side of the transformer accommodating portion 41 opposite to the transformer 20 can be reduced or prevented by the shielding member 90. Consequently, as compared with a case in which the shielding member 90 is not provided between the transformer accommodating portion 41 and the lower cover member 60, the occurrence of eddy currents in the metal lower cover member 60 can be reduced or prevented, and thus eddy current losses can be reduced or prevented.

According to this embodiment, as described above, the shielding member 90 is made of non-magnetic metal having an electrical resistance lower than the electrical resistance of the lower cover member 60. Eddy current losses are proportional to the electrical resistance of a member in which eddy currents occur, and thus eddy current losses due to eddy currents occurring in the shielding member 90 when the leakage magnetic flux of the transformer 20 is interlinked with the shielding member 90 made of non-magnetic metal having an electrical resistance lower than the electrical resistance of the lower cover member 60 are likely to be smaller than eddy current losses due to eddy currents occurring in the lower cover member 60 when the leakage magnetic flux of the transformer 20 is interlinked with the lower cover member 60. Furthermore, the amount of leakage magnetic flux of the transformer 20 interlinked with the lower cover member 60 is reduced by the amount of leakage magnetic flux of the transformer 20 interlinked with the shielding member 90 provided between the transformer accommodating portion 41 and the lower cover member 60. Therefore, the shielding member 90 is made of non-magnetic metal having an electrical resistance lower than the electrical resistance of the housing 40 as described above such that eddy current losses due to eddy currents occurring in the metal lower cover member 60 can be easily reduced or prevented.

According to this embodiment, as described above, the shielding member 90 has a size substantially equal to or larger than the size of the second portion 80 (insulating layer), as viewed in the direction (Z direction) in which the substrate 30 and the housing 40 face each other. Accordingly, the shielding member 90 is relatively large as viewed in the direction in which the substrate 30 and the housing 40 face each other, and thus the leakage magnetic flux of the transformer 20 toward the metal lower cover member 60 can be effectively shielded.

### Modified Examples

The embodiment disclosed this time must be considered as illustrative in all points and not restrictive. The scope of the present invention is not shown by the above description of the embodiment but by the scope of claims for patent, and all modifications (modified examples) within the meaning and scope equivalent to the scope of claims for patent are further included.

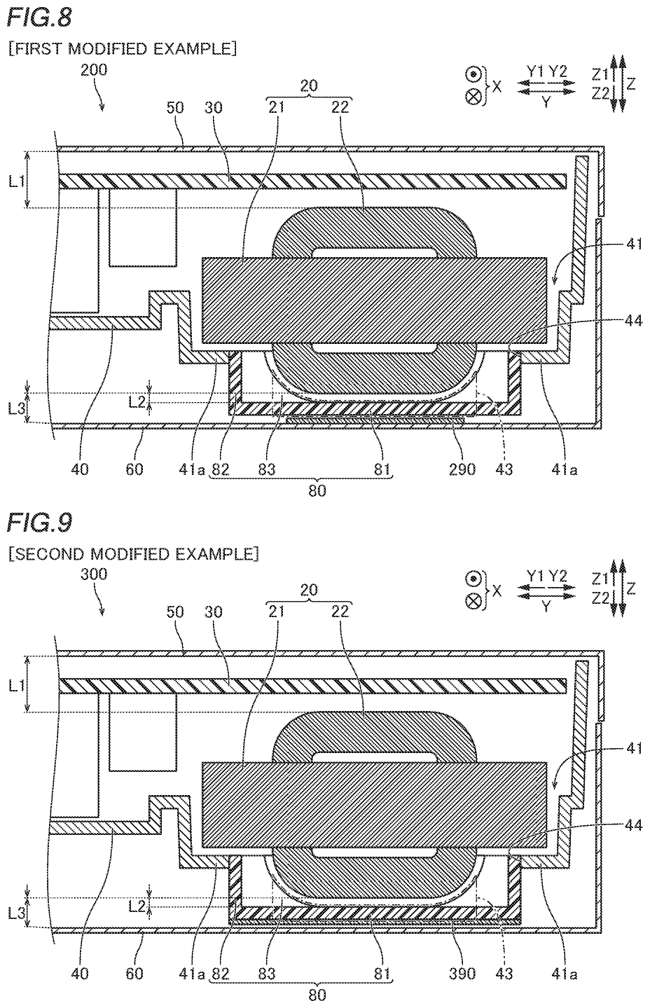

For example, while the shielding member 90 has a size substantially equal to or larger than the size of the second portion 80 (insulating layer), as viewed in the direction in which the substrate 30 and the housing 40 face each other in the aforementioned embodiment, the present invention is not limited to this. In the present invention, as in a power conversion device 200 according to a first modified example of FIG. 8, a shielding member 290 may alternatively have a size smaller than substantially the same size as the size of a second portion 80 (insulating layer), as viewed in a direction (Z direction) in which a substrate 30 and a housing 40 face each other.

While the shielding member 90 is made of non-magnetic metal having an electrical resistance smaller than the electrical resistance of the lower cover member 60 (cover member) in the aforementioned embodiment, the present invention is not limited to this. In the present invention, the shielding member may alternatively be made of ferrite. Ferrite has the effect of attracting a magnetic flux, and thus when the shielding member made of ferrite is provided between the transformer accommodating portion and the cover member, the leakage magnetic flux of the transformer is less likely to be interlinked with the cover member as compared with a case in which the shielding member made of ferrite is not provided between the transformer accommodating portion and the cover member. Therefore, as described above, the shielding member is made of ferrite such that the leakage magnetic flux of the transformer is less likely to be interlinked with the cover member, and thus the occurrence of eddy currents in the cover member can be easily reduced or prevented. Thus, eddy current losses due to eddy currents occurring in the cover member can be easily reduced or prevented. Furthermore, in the present invention, the shielding member may alternatively be made of both non-magnetic metal having an electrical resistance smaller than the electrical resistance of the cover member and ferrite.

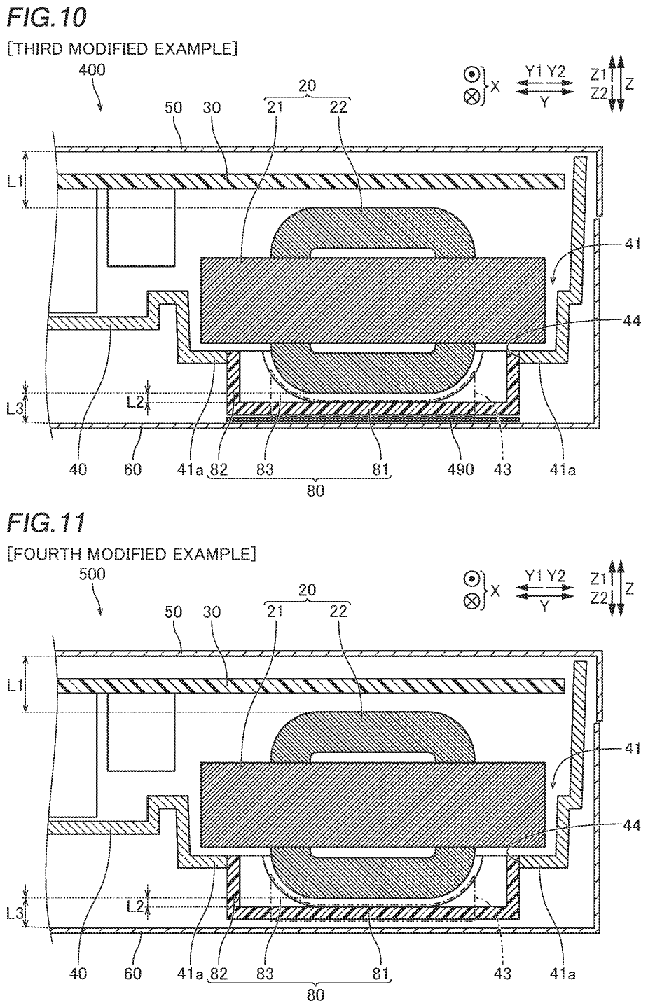

While the shielding member 90 is attached to the lower cover member 60 in the aforementioned embodiment, the present invention is not limited to this. In the present invention, as in a power conversion device 300 according to a second modified example of FIG. 9, a shielding member 390 may alternatively be attached to a transformer accommodating portion 41. Furthermore, in the present invention, as in a power conversion device 400 according to a third modified example of FIG. 10, a shielding member 490 may alternatively be spaced apart from both a transformer accommodating portion 41 and a lower cover member 60 between the transformer accommodating portion 41 and the lower cover member 60.

While the power conversion device 100 includes the plate-shaped shielding member 90 provided between the transformer accommodating portion 41 and the lower cover member 60 to shield the leakage magnetic flux of the transformer 20 in the aforementioned embodiment, the present invention is not limited to this. In the present invention, as shown in a fourth modified example of FIG. 11, a power conversion device 500 may not include a plate-shaped shielding member 90 provided between a transformer accommodating portion 41 and a lower cover member to shield the leakage magnetic flux of a transformer 20. In such a case, the transformer accommodating portion 41 and the lower cover member 60 are preferably spaced apart from each other by a relatively large distance. Furthermore, in the present invention, as in a power conversion device 600 according to a fifth modified example of FIG. 12, a portion of a lower cover member 660 that faces a coil 22 may alternatively be replaced with a shielding member 661 instead of providing the shielding member 90 between the transformer accommodating portion 41 and the lower cover member 60. The lower cover member 660 is an example of a “cover member” in the claims.

While the cooling fins 84 are provided on the surface of the second portion 80 (insulating layer) including an insulating member on the side opposite to the transformer 20 in the aforementioned embodiment, the present invention is not limited to this. In the present invention, the cooling fins may not be provided on the surface of the insulating layer including the insulating member on the side opposite to the transformer.

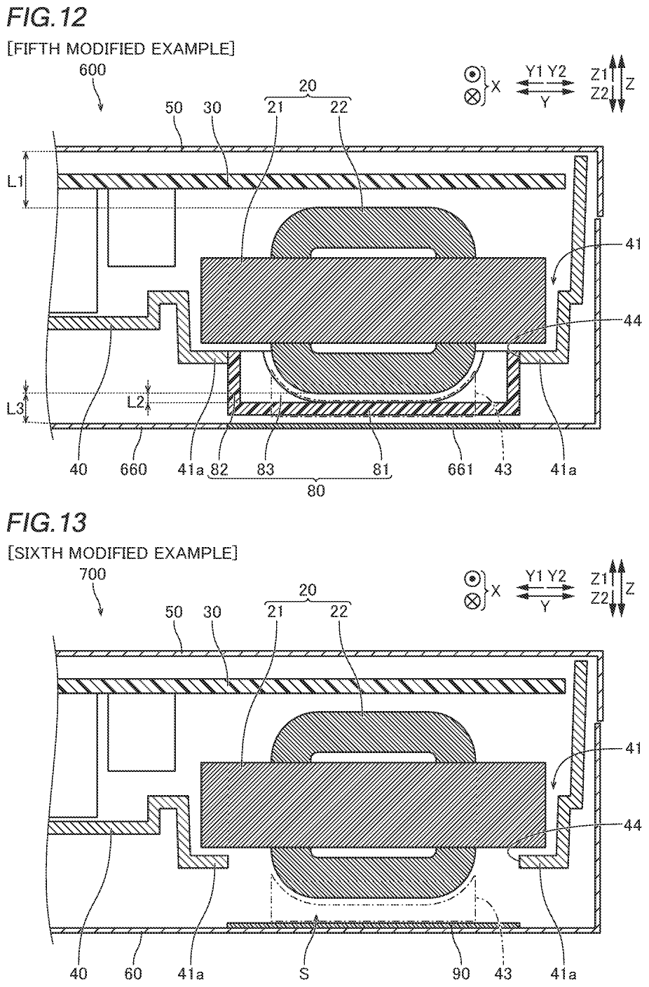

While the second portion 80 (insulating layer) includes the insulating member fitted into the hole 44 provided in the portion 43 of the transformer accommodating portion 41 that faces the coil 22 in the direction (Z direction) in which the substrate 30 and the housing 40 face each other in the aforementioned embodiment, the present invention is not limited to this. In the present invention, as in a power conversion device 700 according to a sixth modified example shown in FIG. 13, an insulating layer may alternatively include a space S corresponding to a hole provided in a portion 43 of a transformer accommodating portion 41 that faces a coil 22 in a direction (Z direction) in which a substrate 30 and a housing face each other. Accordingly, the insulating layer of air can be easily provided in the portion 43 of the transformer accommodating portion 41 that faces the coil 22 in the direction in which the substrate 30 and the housing 40 face each other simply by providing a space in the portion 43 of the transformer accommodating portion 41 that faces the coil 22. Moreover, unlike a case in which the insulating layer includes the insulating member, the insulating member is not required, and thus the number of components can be reduced.

While the second portion 80 formed as the insulating layer includes the bottom 81 facing the coil 22 as viewed in the direction (Z direction) in which the substrate 30 and the housing 40 face each other, and the side portions 82 continuous with the bottom 81, extending along the direction in which the substrate 30 and the housing 40 face each other, and surrounding the coil 22 in the aforementioned embodiment, the present invention is not limited to this. In the present invention, the insulating layer may alternatively include the bottom facing the coil as viewed in the direction in which the substrate and the housing face each other, but may not include the side portions continuous with the bottom, extending along the direction in which the substrate and the housing face each other, and surrounding the coil.

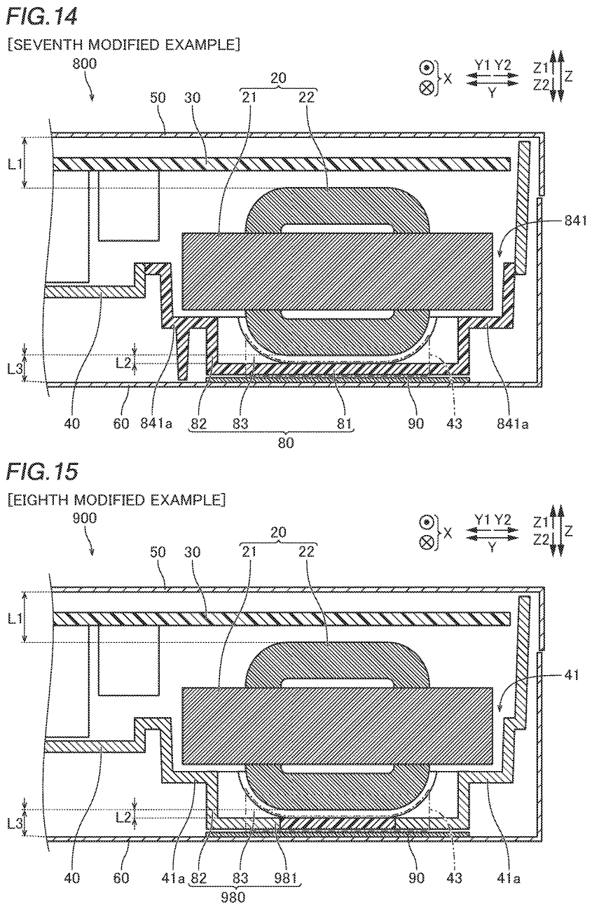

While the transformer accommodating portion 41 of the housing 40 includes the frame-shaped first portion 41a made of metal, in which the core 21 is arranged, and the second portion 80 provided inside the first portion 41a and formed as the insulating layer, in which the coil 22 is arranged, in the aforementioned embodiment, the present invention is not limited to this. In the present invention, as in a power conversion device 800 according to a seventh modified example shown in FIG. 14, a transformer accommodating portion 841 may alternatively include a frame-shaped first portion 841a formed as an insulating layer, in which a core 21 is arranged, and a second portion 80 provided inside the first portion 841a and formed as an insulating layer, in which a coil 22 is arranged. In this case, the first portion 841a and the second portion 80 may be formed integrally or separately. FIG. 14 shows an example in which the first portion 841a and the second portion 80 are integrally formed.

While the insulating layer is provided in the entire portion 43 of the transformer accommodating portion 41 that faces the coil 22 in the direction (Z direction) in which the substrate 30 and the housing 40 face each other in the aforementioned embodiment, the present invention is not limited to this. In the present invention, as in a power conversion device 900 according to an eighth modified example shown in FIG. 15, an insulating layer may alternatively be partially provided in a portion 43 of a transformer accommodating portion 41 that faces a coil 22 in a direction (Z direction) in which a substrate 30 and a housing 40 face each other. FIG. 15 shows an example in which a portion of a bottom 981 of a second portion 980 that faces the coil 22 is partially formed as the insulating layer.

What is claimed is:

1. A power conversion device comprising:
a transformer including a core and a coil wound around the core;
a substrate made of resin, on which the transformer is mounted;
a housing made of metal, arranged on a side of the transformer opposite to the substrate, and including a recessed transformer accommodating portion to accommodate the transformer; and
an insulating layer provided in a portion of the transformer accommodating portion that faces the coil in a direction in which the substrate and the housing face each other.

2. The power conversion device according to claim 1, wherein the transformer accommodating portion of the housing includes a frame-shaped first portion made of metal, in which the core is arranged, and a second portion provided inside the first portion and formed as the insulating layer, in which the coil is arranged.

3. The power conversion device according to claim 2, wherein the second portion formed as the insulating layer includes a bottom facing the coil as viewed in the direction in which the substrate and the housing face each other, and side portions continuous with the bottom, extending along the direction in which the substrate and the housing face each other, and surrounding the coil.

4. The power conversion device according to claim 1, wherein the insulating layer includes an insulating member fitted into a hole provided in the portion of the transformer accommodating portion that faces the coil in the direction in which the substrate and the housing face each other.

5. The power conversion device according to claim 4, further comprising:
a cooling fin provided on a surface of the insulating layer formed of the insulating member on a side opposite to the transformer.

6. The power conversion device according to claim 1, wherein the insulating layer is a space as a hole provided in the portion of the transformer accommodating portion that faces the coil in the direction in which the substrate and the housing face each other.

7. The power conversion device according to claim 1, further comprising:
a cover member made of metal to cover the housing on a side of the transformer accommodating portion opposite to the transformer; and
a plate-shaped shielding member provided between the transformer accommodating portion and the cover member to shield a leakage magnetic flux of the transformer.

8. The power conversion device according to claim 7, wherein the shielding member is made of at least one of non-magnetic metal having an electrical resistance lower than an electrical resistance of the cover member or ferrite.

9. The power conversion device according to claim 7, wherein the shielding member has a size substantially equal to or larger than a size of the insulating layer, as viewed in the direction in which the substrate and the housing face each other.
